(19) United States
(12) Patent Application Publication
(10) Pub. No.: US 2021/0407074 A1
(43) Pub. Date: Dec. 30, 2021

(54) IMAGE PROCESSING METHOD AND IMAGE PROCESSING DEVICE

(71) Applicant: Tokyo Electron Limited, Minato-ku, Tokyo (JP)

(72) Inventor: Shinji KOBAYASHI, Koshi City, Kumamoto (JP)

(21) Appl. No.: 17/290,029

(22) PCT Filed: Aug. 26, 2019
(86) PCT No.: PCT/JP2019/033372

§ 371 Date: Apr. 29, 2021

(30) Foreign Application Priority Data
Nov. 1, 2018 (JP) 2018-206458
Feb. 13, 2019 (JP) 2019-023145

(51) Int. Cl. G06T 7/00; G06T 5/20; G06T 5/00

(52) U.S. Cl. CPC G06T 7/0006; G06T 5/20; G06T 2207/30148; G06T 2207/10061; G06T 2207/20076; G06T 5/002

(57) ABSTRACT

An aspect of the present disclosure is an image processing method for processing an image, wherein the image processing method includes: (A) a step of acquiring multiple frame images, each of which is obtained by scanning an imaging target one time with a charged particle beam, (B) a step of determining, from the multiple frame images, a luminance probability distribution for respective pixels; and (C) a step of generating an image of the imaging target, which corresponds to an image obtained by averaging multiple different frame images generated based on the luminance probability distribution for respective pixels.

### TECHNICAL FIELD

The present disclosure relates to an image processing method and an image processing device.

### BACKGROUND

Patent Document 1 discloses a method of obtaining an image by scanning a pattern on a wafer with an electron beam, wherein an image having a high S/N ratio is formed by integrating signals acquired from multiple frames.

### PRIOR ART DOCUMENT

### Patent Document

Patent Document 1: Japanese Laid-Open Patent Publication No. 2010-92949

The technique according to the present disclosure further reduces noise in an image obtained by scanning an imaging target with a charged particle beam.

### SUMMARY

An aspect of the present disclosure is an image processing method for processing an image, wherein the image processing method includes: (A) a step of acquiring multiple frame images, each of which is obtained by scanning an imaging target one time with a charged particle beam, (B) a step of determining, from the multiple frame images, a luminance probability distribution for each pixel; and (C) a step of generating an image of the imaging target that corresponds to an image obtained by averaging multiple different frame images generated based on the luminance probability distribution for each pixel.

According to the present disclosure, it is possible to further reduce noise in an image obtained by scanning an imaging target with a charged particle beam.

### BRIEF DESCRIPTION OF DRAWINGS

FIG. 1 is a diagram showing illuminance of a specific pixel in each of actual frame images.

FIG. 2 is a histogram of luminance of all pixels whose X coordinates match specific pixels in all 256 frames.

FIG. 3 is a view illustrating an outline of a configuration of a processing system including a control device as an image processing device according to a first embodiment.

FIG. 4 is a block diagram illustrating an outline of a configuration of image processing by a controller.

FIG. 5 is a flowchart illustrating a process executed by the controller of FIG. 4.

FIG. 6 illustrates an image obtained by averaging frame images of 256 frames.

FIG. 7 illustrates an artificial image obtained by averaging artificial frame images of 256 frames generated based on the frame images of 256 frames used for image generation of FIG. 6.

FIGS. 8A to 8C are diagrams showing frequency analysis results for an artificial image generated from 256 frame images, and illustrate a relationship between frequency and an amount of vibration energy.

FIGS. 9A to 9C are diagrams showing frequency analysis results for an artificial image generated from 256 frame images, and illustrate a relationship between the number of frames and a noise level of high-frequency components.

FIG. 10 is an image obtained by averaging 256 virtual frame images having zero process noise.

FIG. 11 is an artificial image obtained by generating 256 artificial frame images based on the 256 virtual frame images used for generating the image of FIG. 10, and averaging these artificial frame images.

FIGS. 12A to 12C are diagrams showing frequency analysis results for an artificial image generated from 256 virtual frame images having zero process noise, and illustrate a relationship between frequency and an amount of vibration energy.

FIGS. 13A to 13C are diagrams showing frequency analysis results for an artificial image generated from 256 virtual frame images having zero process noise, and illustrate a relationship between the number of frames and a noise level of high-frequency components.

FIGS. 14A to 14C are diagrams showing other frequency analysis results for an artificial image generated from 256 frame images when the number of frames of the artificial frame images at the time of generating the artificial image is 256 or less, and illustrate a relationship between frequency and an amount of vibration energy.

FIGS. 15A to 15C are diagrams showing other frequency analysis results for an artificial image generated from 256 frame images when the number of frames of the artificial frame images at the time of generating the artificial image is 256 or less, and illustrate a relationship between the number of frames and a noise level of high-frequency components.

FIG. 16 is a diagram showing an example of in-plane average values of luminance in each of original frame images and in each of artificial frame images when the number of frames of the original frame images and the number of frames of the artificial frame images used for generating an artificial image are both 256.

FIGS. 17A to 17C are diagrams showing frequency analysis results for an artificial image generated from artificial frame images obtained after adjusting luminance of artificial frame images generated from 256 frame images.

FIGS. 18A to 18C are diagrams showing frequency analysis results for an artificial image generated using artificial frame images obtained by shifting the artificial frame images generated from 256 frame images.

FIG. 19 is a view illustrating an infinite frame artificial image generated using a method according to a fourth embodiment.

FIG. 20 is a block diagram illustrating an outline of a configuration of image processing by the controller according to a fifth embodiment.

FIG. 21 is a flowchart illustrating a process executed by the controller of FIG. 20.

FIG. 22 is a diagram for describing a method of acquiring a statistical amount of a feature amount of a pattern on a wafer according to a sixth embodiment.

FIG. 23 is a diagram for explaining a method of acquiring a statistical amount of a feature amount of a pattern on a wafer according to a seventh embodiment.

FIG. 24 is a diagram showing variation in luminance according to an averaging method.

### DETAILED DESCRIPTION

For inspection, analysis, or the like of a fine pattern formed on a substrate, such as a semiconductor wafer (hereinafter, referred to as a “wafer”), in the process of manufacturing a semiconductor device, an image obtained by scanning the substrate with an electron beam is used. Images used for analysis or the like are required to have little noise.

In Patent Document 1, an image having a high S/N ratio, that is, a low-noise image, is formed by integrating signals acquired from multiple frames.

In recent years, further miniaturization of semiconductor devices has been required. Accordingly, further reduction of noise is required for images used for pattern inspection, analysis, or the like.

In addition, further reduction of noise is also required for imaging targets other than a substrate.

Therefore, the technique according to the present disclosure further reduces noise in an image obtained by scanning an imaging target with a charged particle beam. In the following description, an image obtained by scanning a substrate serving as an imaging target one time with an electron beam will be referred to as a “frame image.”

### First Embodiment

A frame image obtained by scanning with an electron beam includes not only image noise caused by an imaging condition or an imaging environment, but also pattern fluctuation caused by the process during pattern formation. Then, for an image used for analysis or the like, it is important to remove and reduce image noise, and not to remove the fluctuation as noise, that is, not to remove stochastic noise, which is a random variation derived from the process.

In order to reduce the image noise, when signals acquired in multiple frames are integrated to form an image as in Patent Document 1, the number of frames may be increased. In other words, the number of times an imaging area is scanned with an electron beam may be increased. However, when the number of frames is increased, a pattern on a wafer, which is an imaging target, or the like is damaged.

Based on this point, the inventor considered acquiring an image with reduced image noise by artificially creating and averaging a large number of different frame images while suppressing the actual number of frames. In order to artificially create the frame images, it is necessary to set a method for determining luminance of pixels in the artificial frame images.

An actual frame image of an imaging target is created based on the results of amplification and detection of secondary electrons generated when the wafer is irradiated with an electron beam. The number of secondary electrons generated when the wafer is irradiated with an electron beam follows a Poisson distribution, and the amplification factor when the secondary electrons are amplified and detected is not constant. In addition, the generation amount of secondary electrons is also affected by the degree of charge-up of the imaging target or the like. Therefore, it is considered that the luminance of pixels corresponding to the portion irradiated with an electron beam in an actual frame image is determined from a certain probability distribution.

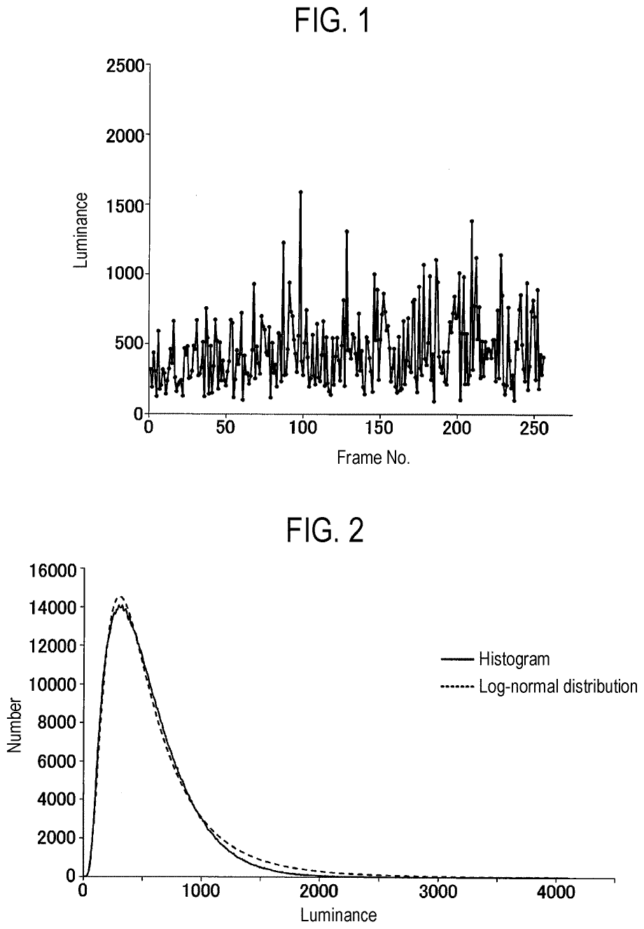

FIGS. 1 and 2 are diagrams showing the results of an earnest investigation performed by the inventor in order to estimate the above-mentioned probability distribution. In this investigation, 256 frames of actual frame images of wafers having line-and-space patterns formed thereon were prepared under the same imaging conditions. FIG. 1 is a diagram showing luminance of a specific pixel in each of the actual frame images. The specific pixel is one pixel corresponding to a center of a space portion of the pattern and considered to have the most stable luminance. FIG. 2 is a histogram of luminance of all pixels whose X coordinates match the specific pixels in all 256 frames. The X coordinates are coordinates in a direction substantially orthogonal to the extension direction of the lines of a pattern on the wafer.

As shown in FIG. 1, in the actual frame images, the luminance of the specific pixel does not appear to be constant between frames, but appears to be irregularly and randomly determined. The histogram of FIG. 2 follows a log-normal distribution.

Based on these results, it is considered that the luminance of the pixels corresponding to a portion irradiated with an electron beam in the actual frame image is determined from a probability distribution according to a log-normal distribution.

Based on the point described above, in the image processing method according to the present embodiment, multiple actual frame images of a wafer are acquired from the same coordinates and, from the acquired multiple frame images, a luminance probability distribution according to a log-normal distribution is determined for each pixel. Then, multiple different artificial frame images (hereinafter, referred to as “artificial frame images”) are generated, for example, by generating random numbers based on the luminance probability distribution for each pixel, and an artificial image is generated as an image of an imaging target by averaging the multiple artificial frame images. According to this method, since it is possible to generate a large number of artificial frame images from an actual frame image, it is possible to reduce image noise in the finally generated artificial image compared with an image obtained by averaging multiple actual frame images. In addition, it is not necessary to increase the number of times an electron beam scans in order to obtain an actual frame image. Therefore, it is possible to reduce image noise while suppressing damage to the pattern on the wafer or the like. In addition, in the present embodiment, only image noise is reduced, and it is possible to prevent the stochastic noise derived from the process from being removed.

Hereinafter, the configuration of a substrate processing apparatus according to the present embodiment will be described with reference to the drawings. In this specification, elements having substantially the same functional configurations will be denoted by the same reference numerals, and redundant descriptions will be omitted.

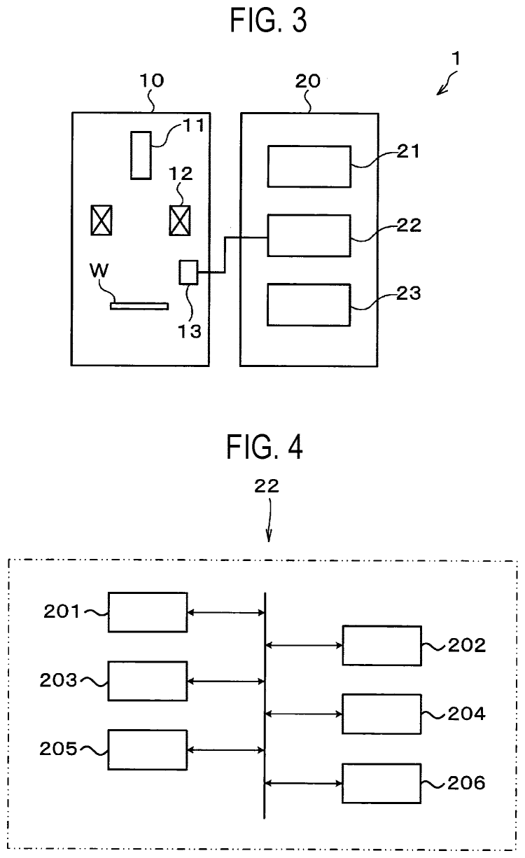

FIG. 3 is a view illustrating an outline of a configuration of a processing system including a control device serving as an image processing device according to a first embodiment.

The processing system 1 of FIG. 3 includes a scanning electron microscope 10 and a control device 20.

The scanning electron microscope 10 includes an electron source 11 configured to emit an electron beam as a charged particle beam, a deflector 12 configured to two-dimensionally scan an imaging area of a wafer W as a substrate with an electron beam from the electron source 11, and a detector 13 configured to amplify and detect secondary electrons generated from the wafer W by irradiation with the electron beam.

The control device 20 includes a storage part 21 configured to store various kinds of information, a controller 22 configured to control the scanning electron microscope 10 and to control the control device 20, and a display part 23 configured to perform various displays.

FIG. 4 is a block diagram illustrating an outline of a configuration of the controller 22 related to image processing.

The controller 22 is configured with, for example, a computer including a CPU, a memory, and the like, and includes a program storage part (not illustrated). The program storage part stores programs for controlling various processes in the controller 22. The programs may be recorded in a computer-readable storage medium, and may be installed in the controller 22 from the storage medium. Some or all of the programs may be implemented by dedicated hardware (a circuit board).

As illustrated in FIG. 4, the controller 22 includes a frame image generation part 201, an acquisition part 202, a probability distribution determination part 203, an artificial image generation part 204 serving as an image generation part, a measurement part 205, and an analysis part 206.

The frame image generation part 201 sequentially generates multiple frame images based on the results of detection by the detector 13 of the scanning electron microscope 10. The frame image generation part 201 generates frame images having a specified number of frames (e.g., 32). In addition, the generated frame images are sequentially stored in the storage part 21.

The acquisition part 202 acquires multiple frame images stored in the storage part 21 and generated by the frame image generation part 201.

The probability distribution determination part 203 determines a luminance probability distribution according to a log-normal distribution for each pixel from the multiple frame images acquired by the acquisition part 202.

The artificial image generation part 204 generates artificial frame images having a specified number of frames (e.g., 1024) based on the luminance probability distribution for each pixel. In addition, the artificial image generation part 204 generates an artificial image corresponding to an image obtained by averaging the artificial frame images with the specified number of frames.

The measurement part 205 performs measurement based on the artificial image generated by the artificial image generation part 204.

The analysis part 206 performs analysis based on the artificial image generated by the artificial image generation part 204.

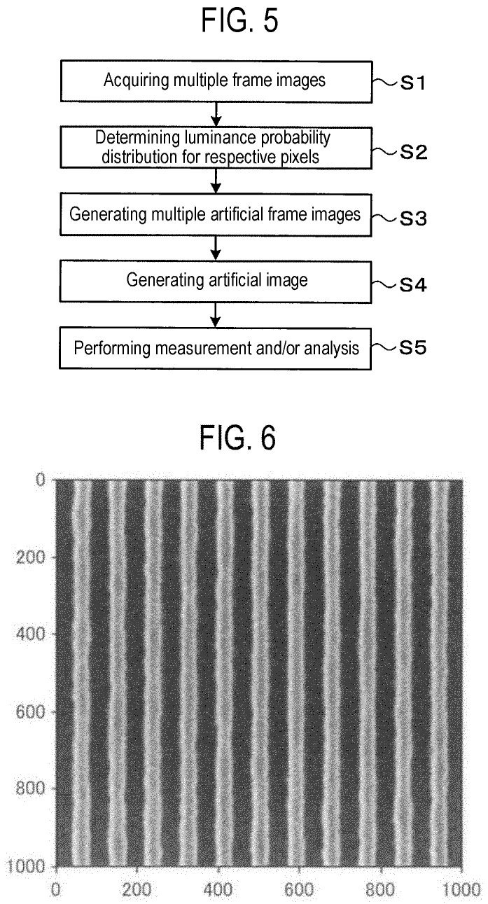

FIG. 5 is a flowchart illustrating a process executed by the controller 22. In the following process, it is assumed that the scanning electron microscope 10 has scanned an electron beam for the number of frames specified by the user in advance under the control of the controller 22 and that the frame image generation part 201 has generated frame images for the specified number of frames. In addition, it is assumed that the generated frame images are stored in the storage part 21.

In the process executed by the controller 22, first, the acquisition part 202 acquires frame images for the specified number of frames from the storage part 21 (step S1). The specified number of frames is, for example, 32, but may be larger or smaller than 32, as long as there are multiple frames. An image size and an imaging area are common between acquired frame images. In addition, the image size of an acquired frame is, for example, 1,000×1,000 pixels, and the size of the imaging area is an area of 1,000 nm×1,000 nm.

Next, the probability distribution determination part 203 determines, for each pixel, a luminance probability distribution of the pixel according to a log-normal distribution (step S2). Specifically, the log-normal distribution is represented by the following Equation 1, and the probability distribution determination part 203 calculates parameters μ and σ, which determine, for each pixel, the log-normal distribution which the luminance probability distribution of the pixel follows.

$$\begin{matrix}[ Number 1 ] & \\ f ( x ) = \frac{1}{\sqrt{2 π} σ x} exp ( - \frac{{( ln x - μ )}^{2}}{2 {σ}^{2}} ) , 0 < x < ∞ & ( 1 )\end{matrix}$$

Subsequently, the artificial image generation part 204 sequentially generates artificial frame images for the number of frames specified by the user based on the luminance probability distribution for each pixel (step S3). In order to reduce image noise, the number of frames of artificial frame images may be plural, but is preferably larger than the number of frames of original frame images. In addition, the size of the artificial frame images and the size of the original frame images are equal to each other.

Specifically, the artificial frame images are images obtained by setting the luminance of each pixel to random values generated according to the probability distribution described above. That is, in step S3, the artificial image generation part 204 generates random numbers, for example, for each pixel, from the two specific parameters μ and σ calculated for each pixel in step S2 that determine a log-normal distribution which the probability distribution follows, by the number corresponding to the specified number of frames.

Next, the artificial image generation part 204 generates an artificial image by averaging the generated artificial frame images (step S4). The size of the artificial image is the same as that of the original frame images or the artificial frame images.

Specifically, in step S4, for each pixel of the artificial frame images, the random values generated by the number corresponding to the specified number of frames in step S3 are averaged, and the averaged value is set to the luminance of a pixel of the artificial image corresponding to the pixel.

Then, the measurement part 205 performs measurement based on the artificial image generated by the artificial image generation part 204, and/or the analysis part 206 performs analysis based on the artificial image generated by the artificial image generation part 204 (step S5). The artificial image may be displayed on the display part 23 simultaneously with the measurement and analysis or before and after the measurement and analysis.

The measurement performed by the measurement part 205 is a measurement of feature amounts of the pattern on the wafer W. The feature amounts include at least one of, for example, a line width, a line width roughness (LWR), a line edge roughness (LER) in the lines of the pattern, a width of a space between the lines of the pattern, a pitch of the lines of the pattern, and a center of gravity of the pattern.

The analysis performed by the analysis part 206 is an analysis of the pattern on the wafer W. The analysis performed by the analysis part 206 is at least one of, for example, frequency analysis of a line width roughness, frequency analysis of a line edge roughness of the pattern, and frequency analysis of a line center (backbone) roughness in the lines of the pattern. When performing the measurement of the feature amounts of the lines of the pattern or the frequency analysis on the lines, the lines are detected based on the luminance of each pixel prior to the measurement and analysis.

Hereinafter, the artificial image generated by the control device 20 serving as an image processing device according to the present embodiment will be described. In the following description, it is assumed that a line-and-space pattern is formed in an imaging area of the wafer W.

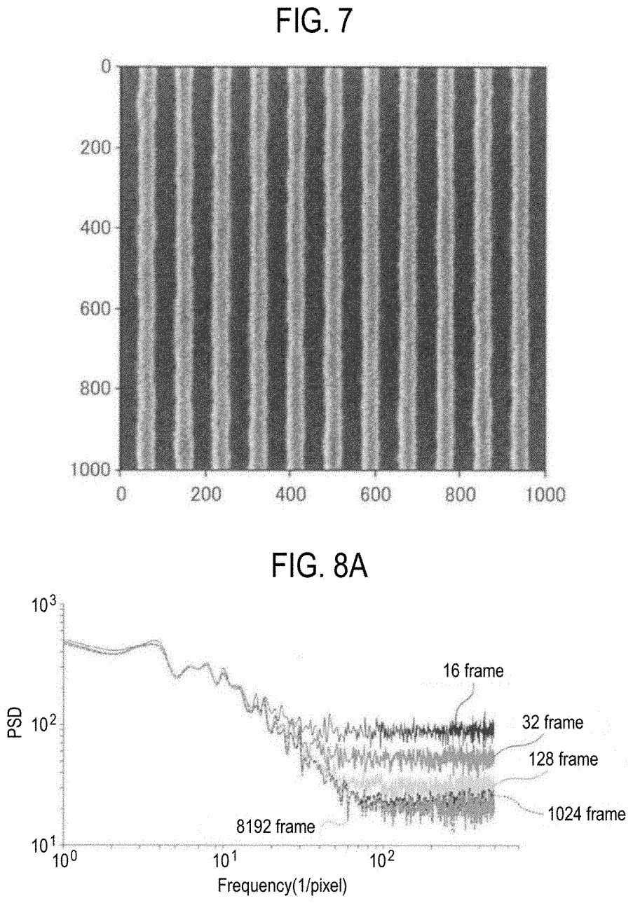

FIG. 6 illustrates an image obtained by averaging 256 frames of frame images. FIG. 7 illustrates an artificial image obtained by averaging 256 frames of artificial frame images generated based on 256 frames of frame images used for generating the image of FIG. 6.

As illustrated in FIGS. 6 and 7, the artificial image generated by the process according to the present embodiment has substantially the same content as the image obtained by averaging original frame images. That is, it is possible to generate an artificial image having the same content as the original image through the image processing according to the present embodiment.

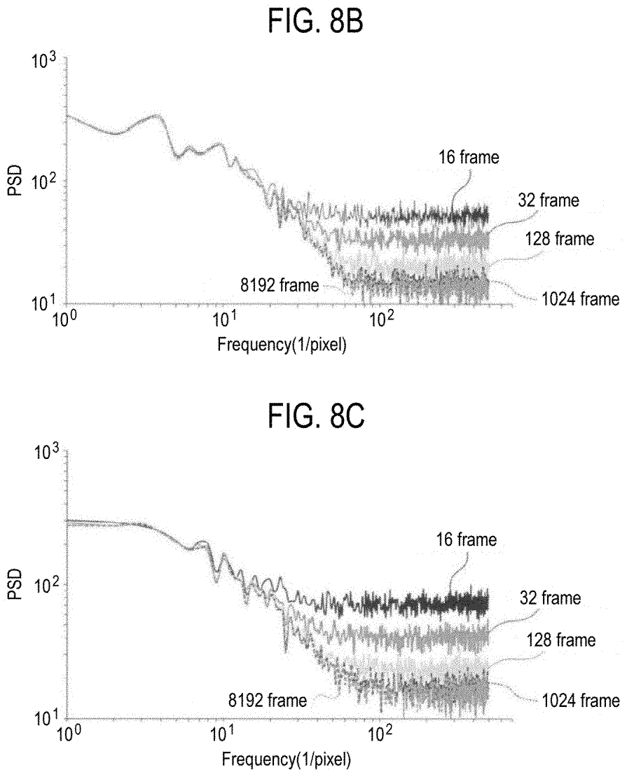

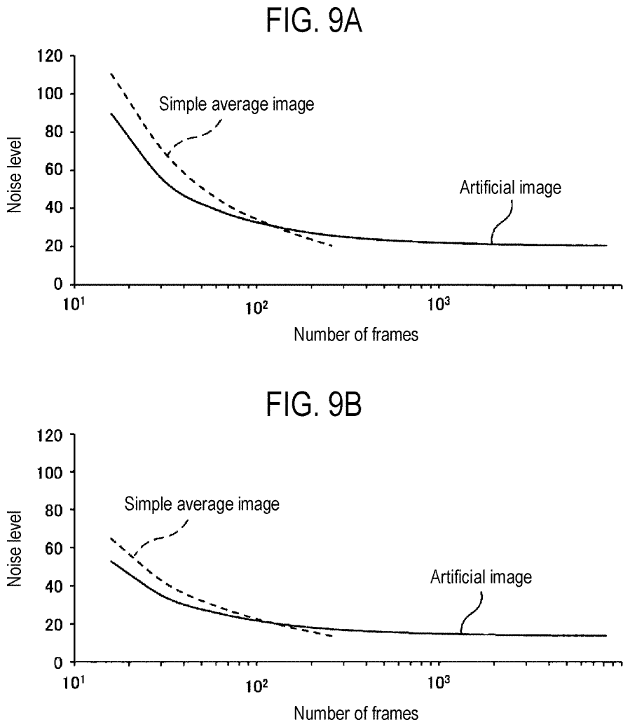

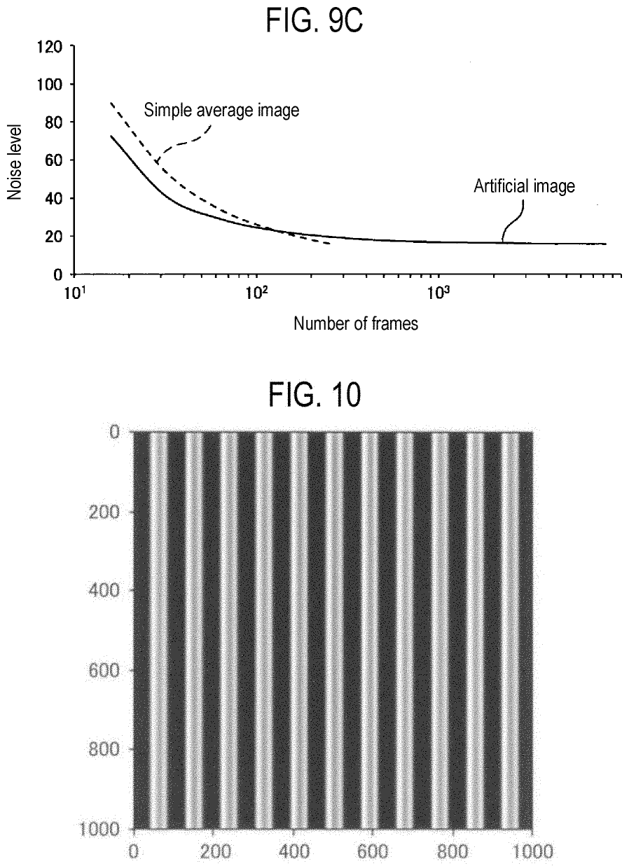

FIGS. 8A to 8C and FIGS. 9A to 9C are diagrams showing frequency analysis results for the artificial image generated from 256 frame images. Each of FIGS. 8A to 8C shows a relationship between frequency and the amount of vibration energy (power spectrum density (PSD)). Each of FIGS. 9A to 9C shows a relationship between the number of frames of artificial frame images used for an artificial image or the number of frames of frame images used for a simple average image to be described later and a noise level of high-frequency components. Here, the high-frequency components correspond to a portion in which the frequency in the frequency analysis is 100 (1/pixel) or higher, and the noise level is an average value of PSDs of the high-frequency components. In addition, each of FIGS. 8A and 9A shows frequency analysis results for the LWR of lines included in a pattern. Each of FIGS. 8B and 9B shows frequency analysis results for the LER on the left side of the lines (hereinafter, referred to as “LLER”), and each of FIGS. 8C and 9C shows frequency analysis results for the LWR on the right side of the lines (hereinafter, referred to as “RLER”). In addition, each of FIGS. 9A to 9C shows frequency analysis results for an image obtained by averaging the first N images (where N is a natural number of 2 or more) among 256 original frame images (hereinafter, the image obtained by averaging frame images will be referred to as a “simple average image”). Here, the image obtained by averaging N images is an image obtained by simply averaging the luminance for each pixel, that is, by arithmetically averaging the luminance for each pixel. Here, in the frequency analysis of images, a simple smoothing filter and a Gaussian filter generally used for the frequency analysis of images were not used at all.

In the frequency analysis of the LWR in an artificial image, as shown in FIG. 8A, the PSD of the high-frequency components decreases as the number of frames of the artificial frame images used for the artificial image increases. In addition, as shown in FIG. 9A, the noise level decreases as the number of frames of the artificial frame images increases, but does not become zero, and becomes constant at a certain positive value.

As shown in FIGS. 8B and 8C and FIGS. 9B and 9C, the same applies to the frequency analysis of LLER and RLER.

That is, in an ultra-high frame artificial image, image noise is removed, but a certain amount of noise remains. This noise is considered to be stochastic noise derived from the process (which may be simply referred to as “process noise” below).

It is impossible to actually form a pattern having zero process noise. Therefore, multiple frame images of the wafer W having zero process noise were virtually created, and artificial frame images and an artificial image were generated from the frame images using the processing method according to the present embodiment. In addition, the nₜₕ frame image virtually created here and having zero process noise is obtained by setting the luminance of pixels having the same X coordinate to an average value of luminance of the pixels having the same X coordinate in the nₜₕ actual frame image.

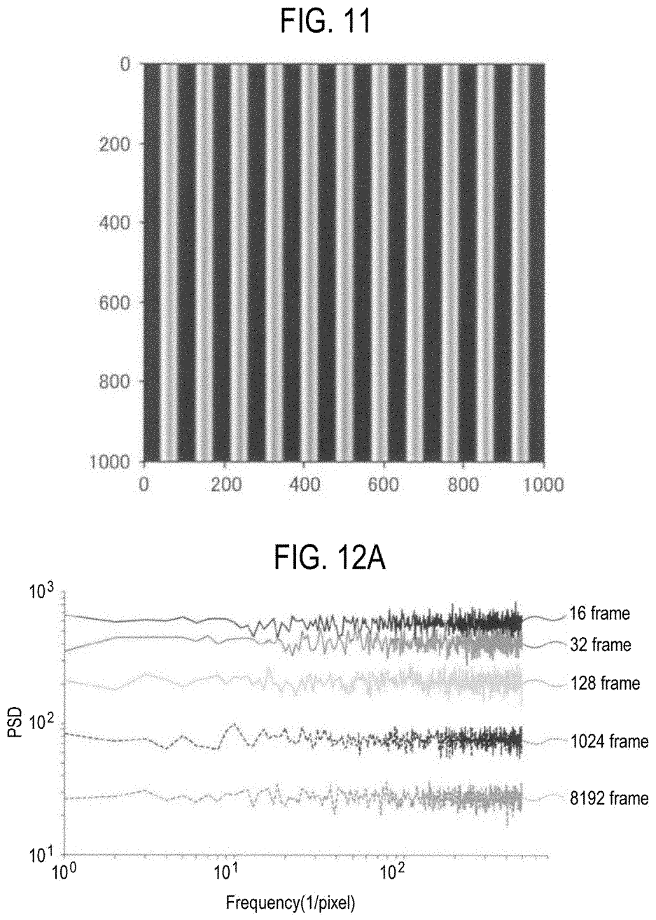

FIG. 10 is an image obtained by averaging 256 virtual frame images having zero process noise. FIG. 11 illustrates an artificial image. This artificial image is obtained by generating artificial frame images of 256 frames based on the virtual frame images of 256 frames used for generating the image of FIG. 10 and averaging these artificial frame images. As illustrated in FIGS. 10 and 11, even when the virtual frame images having zero process noise were used, the artificial image generated using the process according to the present embodiment has substantially the same content as the image obtained by averaging the original virtual frame images.

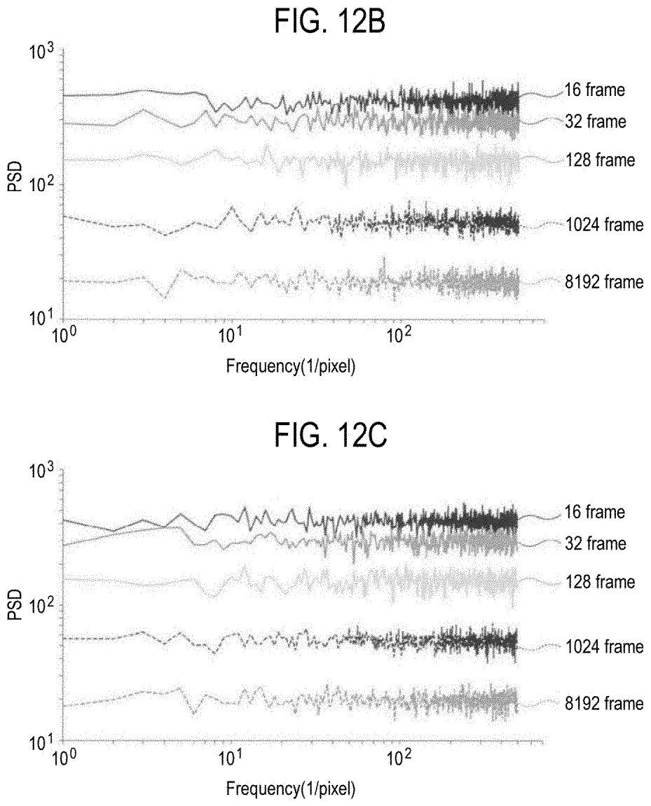

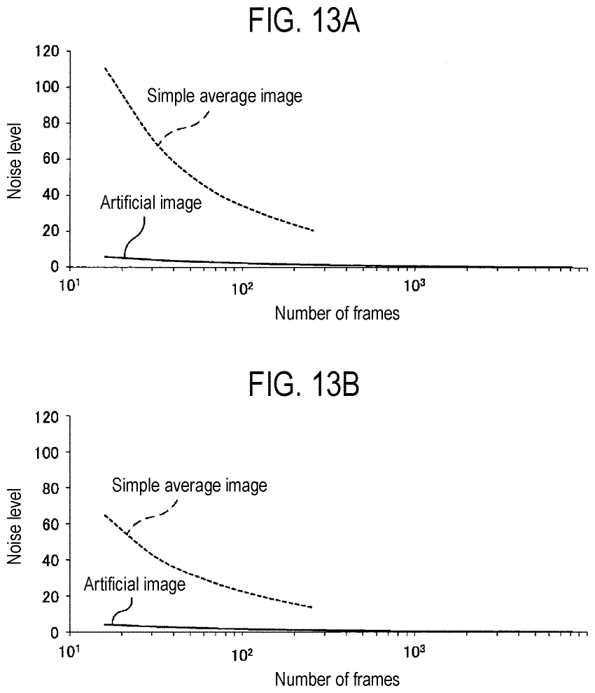

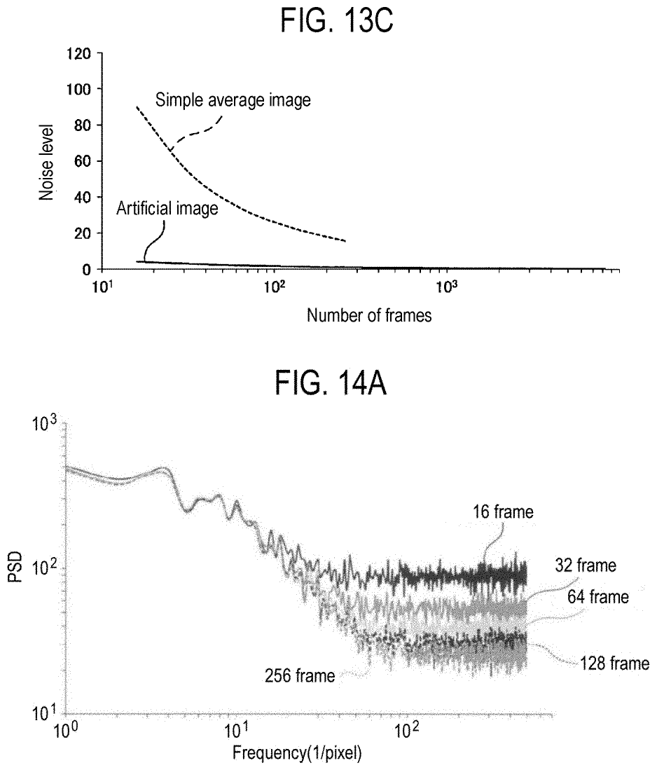

FIGS. 12A to 12C and FIGS. 13A to 13C are diagrams showing frequency analysis results for an artificial image generated from 256 virtual frame images having zero process noise. Each of FIGS. 12A to 12C shows a relationship between frequency and a PSD. Each of FIGS. 13A to 13C shows a relationship between the number of frames of the artificial frame images used for the artificial image and a noise level of high-frequency components. In addition, each of FIGS. 12A and 13A shows frequency analysis results for LWR. Each of FIGS. 12B and 13B shows frequency analysis results for an LLER, and each of FIGS. 12C and 13C shows frequency analysis results for an RLER. Each of FIGS. 13A to 13C also shows frequency analysis results for the simple average image described above.

When virtual frame images having zero process noise are used, in the frequency analysis of an LWR in an artificial image, as illustrated in FIG. 12A, the PSD decreases as the number of frames of the artificial frame images used for the artificial image increases. In addition, as illustrated in FIG. 13A, the noise level decreases as the number of frames of the artificial frame images increases, and becomes almost zero when the number of frames is a certain number or more (e.g., 1,000 or more).

As illustrated in FIGS. 12B and 12C and FIGS. 13B and 13C, the same applies to the frequency analysis of an LLER and an RLER.

That is, when the process noise is zero, the image noise is removed in an ultra-high frame artificial image, and the noise of the entire image becomes zero.

As described above,

(i) when there is process noise, the noise level decreases as the number of frames of artificial frames increases, but even if the number of frames of virtual frame images is very large, the noise in the artificial image does not become zero, and
(ii) further, when the process noise is set to virtually zero, if the number of frames of virtual frame images is large, the noise in the artificial image becomes zero.
From the above items (i) and (ii), it can be said that, according to the image processing method of the present embodiment, it is possible to generate an image from which only image noise is removed and in which process noise remains.

Further, in the present embodiment, it is possible to obtain an artificial image even if the number of frames of the actual frame images obtained by scanning with an electron beam is small. In addition, the smaller the number of frames of actual frame images used to generate an artificial image, the less the pattern on the wafer is damaged by the electron beam. Therefore, according to the present embodiment, it is possible to obtain an image of a pattern that is not damaged by an electron beam, that is, an image in which more accurate process noise is reflected.

### (Further Consideration on Artificial Image)

### (Consideration 1)

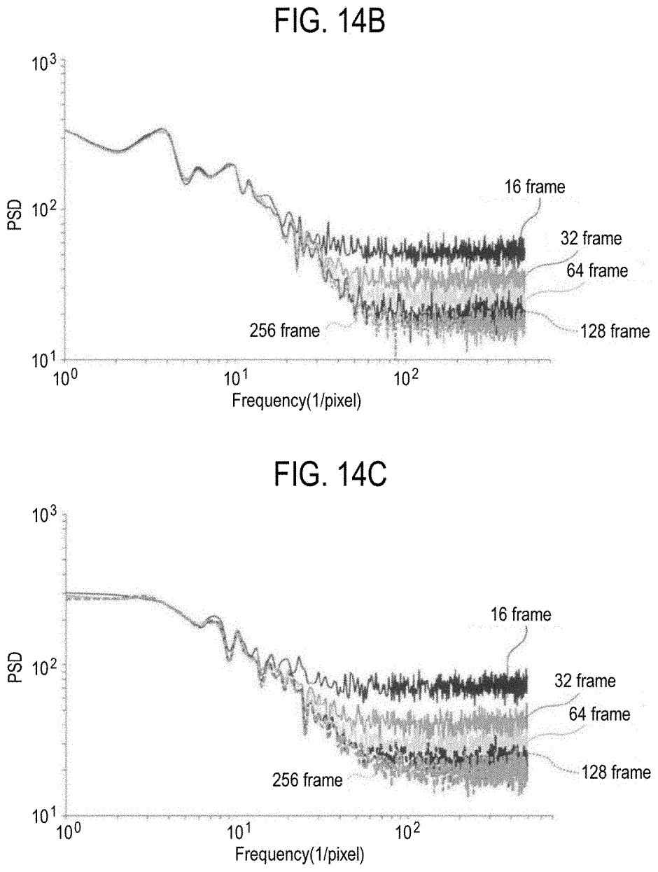

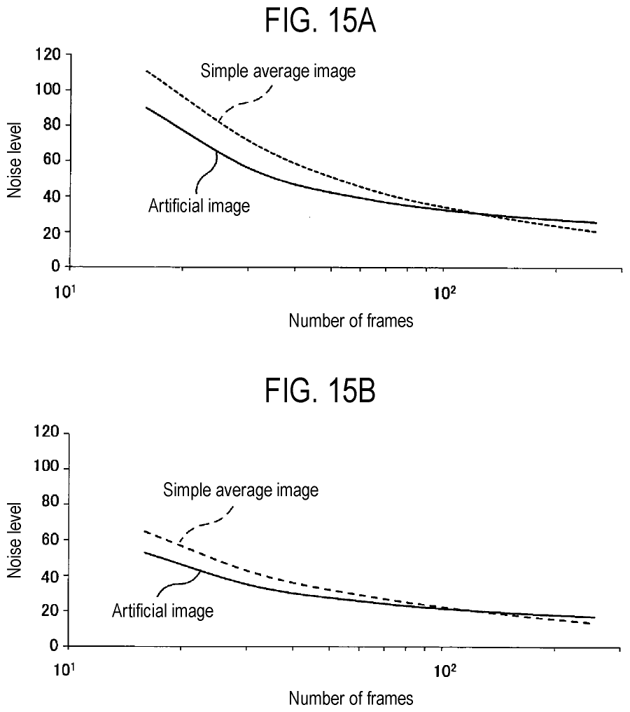

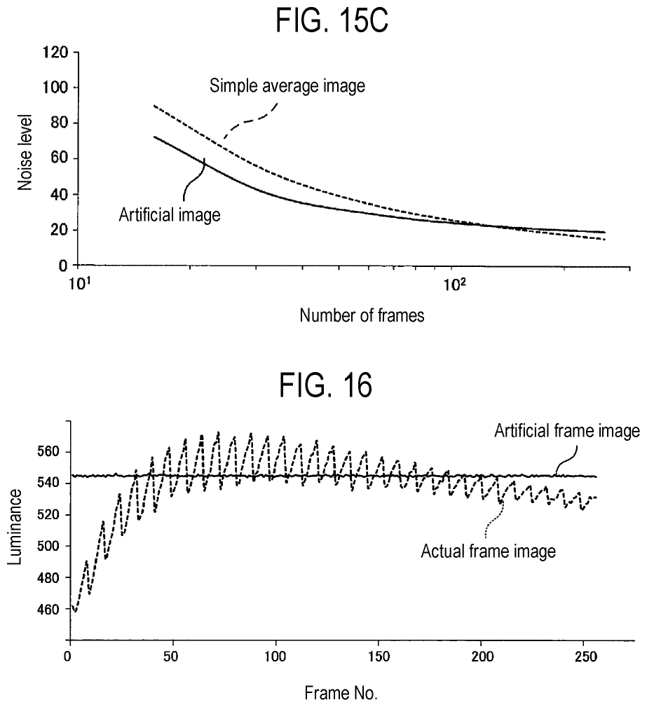

FIGS. 14A to 14C and 15A to 15C are diagrams showing other frequency analysis results for an artificial image generated from 256 frame images, and show the results when the number of frames of the artificial frame images at the time of artificial image generation is 256 or less. Each of FIGS. 14A to 14C shows a relationship between frequency and a PSD. Each of FIGS. 15A to 15C shows a relationship between the number of frames of artificial frame images used for an artificial image or the number of frames of frame images used for a simple average image and the noise level of high-frequency components. The noise level is an average value of PSDs of the high-frequency components. In addition, each of FIGS. 14A and 15A shows frequency analysis results for an LWR. Each of FIGS. 14B and 15B shows frequency analysis results for an LLER, and each of FIGS. 14C and 15C shows frequency analysis results for an RLER. Each of FIGS. 15A to 15C also shows frequency analysis results for the first N simple average image among 256 original frame images.

As shown in FIGS. 14A to 14C, in the frequency analysis of any of the LER, the LLER, and the LRER, the PSD decreases as the frequency increases, and in the high-frequency portion, the PSD decreases as the number of frames at the time of artificial image generation increases. Although not shown, similar results are obtained with the first N simple average image among 256 original frame images.

As shown in FIGS. 15A to 15C, in the artificial image, the noise level of high-frequency components decreases as the number of frames of artificial frame images that are used increases. In addition, in the simple average image, the noise level of high-frequency components decreases as the number of frames of frame images that are used increases.

However, although the tendency of the noise level is similar between the artificial image and the simple average image, the absolute values of the noise levels are different.

FIG. 16 shows an example of in-plane average values of luminance of respective original frame images and respective artificial frame images when the number of frames of the original frame images and the number of frames of the artificial frame images used for generating an artificial image are both 256.

In the original frame images, the in-plane average of luminance shows a certain tendency in a direction of the number of frames, but is not constant. In contrast, in the artificial frame images, the in-plane average of luminance is constant. The change in the in-plane average of luminance during imaging in the original frame images is caused by the imaging conditions and the imaging environment.

Therefore, the luminance of the artificial frame images was adjusted such that the average value of luminance of the Mₜₕ artificial frame image (M is a natural number) is the same with the average value of luminance of the Mₜₕ frame image, and an artificial image was generated by averaging the artificial frame images after the adjustment.

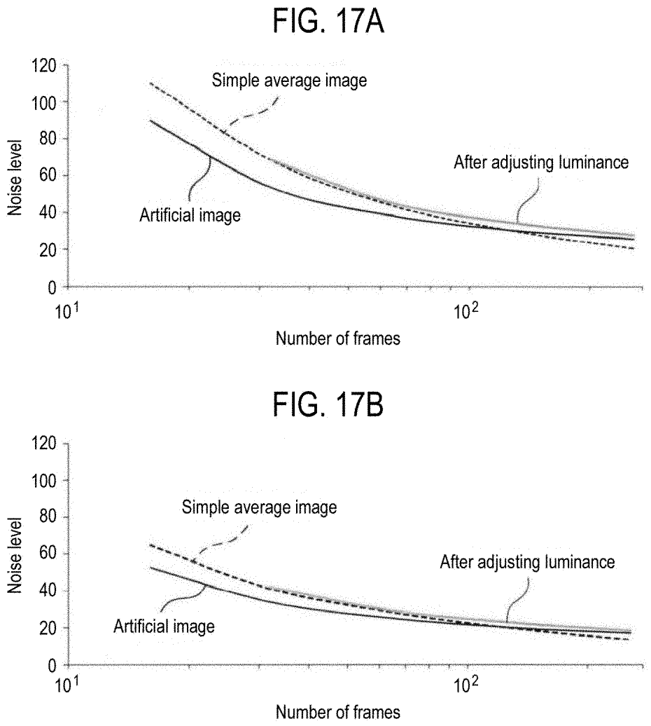

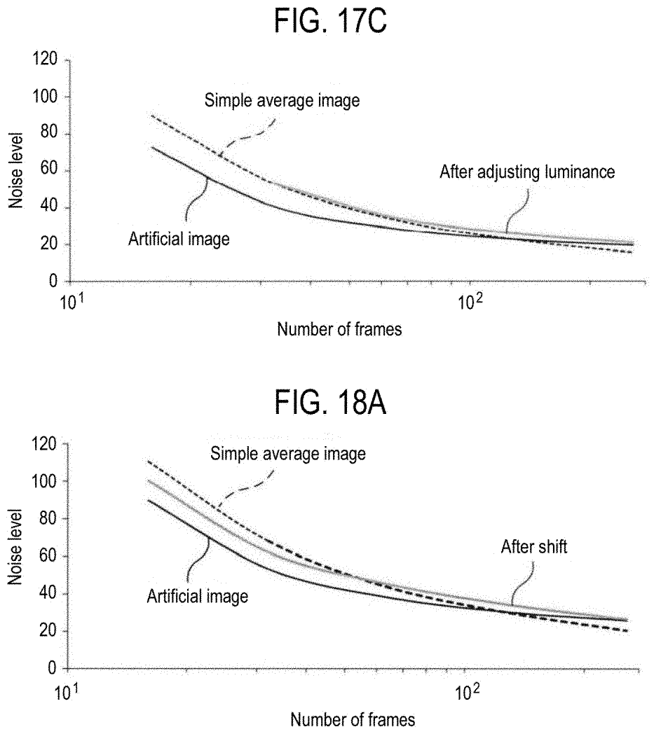

FIGS. 17A to 17C are diagrams showing frequency analysis results for an artificial image generated from artificial frame images obtained after luminance adjustment performed by adjusting the luminance of the artificial frame images generated from 256 frame images as described above. FIGS. 17A to 17C are diagrams showing frequency analysis results for an LWR, an LLER, and an RLER, respectively.

As shown in FIGS. 17A to 17C, the noise levels of high-frequency components of the artificial image generated from the artificial frame images after luminance adjustment approach those of the simple average image of the frame images.

From these results, it can be seen that the change in luminance during imaging affects the noise level of high-frequency components.

### (Consideration 2)

As described above, the in-plane average of luminance in the original frame images changes during imaging depending on the imaging conditions or the like. In addition, the imaging area changes depending on the imaging conditions or the like.

Therefore, the artificial frame images of the second and subsequent frames were gradually shifted in an image plane, the shift amount was increased together with the frame number, and the final artificial frame image was shifted by 10 pixels in the image plane. Then, an artificial image was generated using the artificial frame images after the shift.

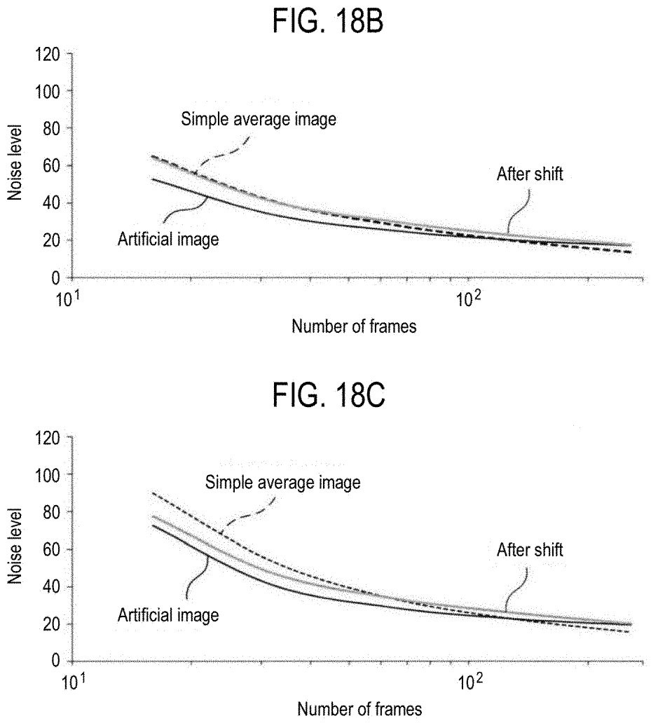

FIGS. 18A to 18C are diagrams showing frequency analysis results for an artificial image generated using artificial frame images obtained by shifting the artificial frame images generated from 256 frame images as described above. FIGS. 18A to 18C are diagrams showing frequency analysis results for an LWR, an LLER, and an RLER, respectively.

As shown in FIGS. 18A to 18C, the noise levels of high-frequency components of the artificial image approach the noise levels of high-frequency components of the simple average image of the frame images when the artificial image is generated using the artificial frame images shifted in the image plane as described above.

From this result, it can be seen that the change in the imaging area during imaging, in other words, the positional deviation between the frame images, affects the noise level of the high-frequency components of the artificial image.

### (Consideration 3)

Since a pattern on a wafer W is gradually damaged during imaging, the critical dimension (CD) of the pattern also changes depending on the imaging conditions and the like. A change in the CD of the pattern appears as a change in the luminance of corresponding pixels in the frame images. Thus, as is clear from Consideration 1 above, the change in the CD of the pattern during imaging affects the noise level of the high-frequency components of the artificial image.

### Second Embodiment

Based on Considerations 1 and 3 above, in the present embodiment, the probability distribution determination part 203 corrects, for respective pixels in respective frame images of the second and subsequent frames, the luminance of the pixels based on a temporal change in the luminance of the pixels in a series of frame images. Then, the probability distribution determination part 203 determines, from multiple frame images including the corrected frame images of the second and subsequent frames, a luminance probability distribution according to a log-normal distribution, for respective pixels. Hereinafter, a more detailed description will be given.

First, the probability distribution determination part 203 acquires, for each pixel in each of the frame images of the second and subsequent frames, information on the temporal change in the luminance of the pixel in a series of frame images. This information on the temporal change may be calculated and acquired from the multiple frame images acquired by the acquisition part 202 whenever required, or may be acquired in advance from an external device. Next, the probability distribution determination part 203 corrects, for each pixel in each of the frame images of the second and subsequent frames, the luminance of the pixel based on the information on the temporal image such that the luminance of the pixel becomes constant regardless of time. For example, the luminance of the pixels is corrected so as to be the same as the luminance of the pixel in the first frame image. Then, from the corrected frame images of the second and subsequent frames and the frame image of the first frame, the probability distribution determination part 203 calculates, for each pixel, parameters μ and σ, which determine a log-normal distribution that the probability distribution of the luminance at the pixel follows.

Based on the parameters μ and σ generated for each pixel from the multiple frame images including the corrected frame images, the artificial image generation part 204 generates multiple artificial frame images and generates an artificial image by averaging these artificial frame images.

According to the present embodiment, it is possible to remove noise generated due to a change in luminance and a change in CD during imaging of the same portion.

Further, in the examples described above, with respect to each of the frame images of the second and subsequent frames, luminance is corrected for each pixel, that is, on a pixel basis. Alternatively, luminance may be corrected on a frame basis with respect to each of the frame images of the second and subsequent frames. Specifically, the probability distribution determination part 203 first acquires information on average luminance of the frame image for all frames, and acquires information on the temporal change in the average luminance. Then, the probability distribution determination part 203 corrects the luminance of each pixel of each frame image such that the average luminance of all of the frames becomes constant. Then, the probability distribution determination part 203 calculates the parameters μ and σ for each pixel from the corrected frame images, and the artificial image generation part 204 creates an artificial image in the same manner as described above based on the parameters μ and σ.

### Third Embodiment

Based on Consideration 2 above, in the present embodiment, the probability distribution determination part 203 corrects each of the frame images of the second and subsequent frames based on a shift amount in an image plane from the frame image of the first frame. As a result, after the correction, the shift amount in the image plane is set to zero between the original frame images. The information on the shift amount may be calculated and acquired from the multiple frame images acquired by the acquisition part 202 whenever required, or may be acquired in advance from an external device.

Then, the probability distribution determination part 203 determines, from the multiple frame images including the corrected frame images of the second and subsequent frames, a luminance probability distribution according to a log-normal distribution, for each pixel. Specifically, using the corrected frame images of the second and subsequent frames, the probability distribution determination part 203 calculates, for each pixel, parameters μ and σ, which determine a log-normal distribution that the probability distribution of luminance at the pixel follows.

The artificial image generation part 204 generates multiple artificial frame images based on the above parameters μ and σ, and generates an artificial image by averaging these artificial frame images.

According to the present embodiment, it is possible to remove noise based on a change, i.e., an image shift, in the imaging area during imaging.

### Fourth Embodiment

In the embodiments described above, an artificial image generation step is constituted with two steps, namely step S3 and step S4.

In the present embodiment, the number of frames of artificial frame images used for an artificial image is infinite. In such a case, the artificial image generation step may be constituted with one step, i.e., the step in which the artificial image generation part 204 generates an image, in which the luminance of each pixel is set to an expected value of the luminance probability distribution, as an artificial image.

The expected value may be represented by the following Formula 2 using the specific parameters μ and σ of a log-normal distribution that the probability distribution of luminance at each pixel follows.

exp(μ+σ²/2) (2)

Further, hereinafter, an artificial image in which the number of frames of used artificial frame images is infinite will be referred to as an “infinite frame artificial image.”

According to the present embodiment, it is possible to generate an image in which only image noise is removed and process noise is left by using a small operation amount.

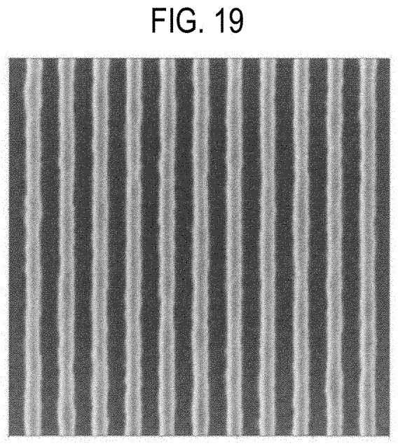

FIG. 19 shows an infinite frame artificial image generated using the method according to the fourth embodiment.

As illustrated in FIG. 19, according to the present embodiment, it is possible to obtain a clearer artificial image.

### Fifth Embodiment

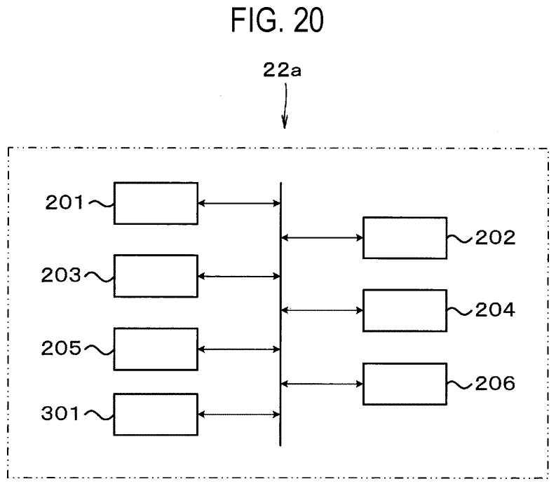

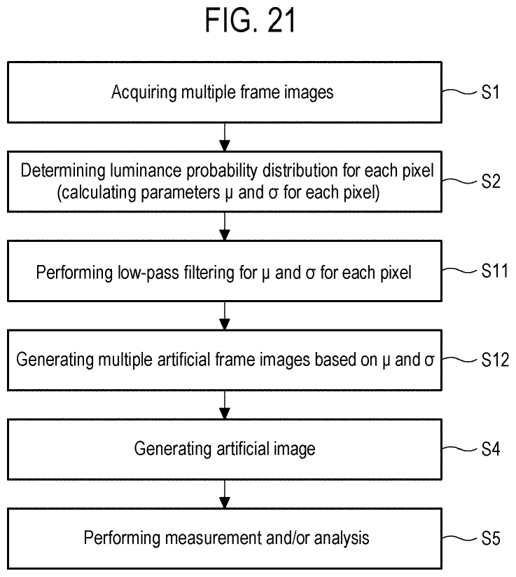

FIG. 20 is a block diagram illustrating an outline of a configuration of image processing by a controller 22a according to a fifth embodiment. FIG. 21 is a flowchart illustrating a process executed by the controller 22a.

Like the controller 22 according to the first embodiment, the controller 22a includes a frame image generation part 201, an acquisition part 202, a probability distribution determination part 203, an artificial image generation part 204, a measurement part 205, and an analysis part 206, as illustrated in FIG. 20. In addition, the controller 22a has a filter part 301 configured to perform low-pass filtering on two specific parameters μ and σ, which determine a log-normal distribution that the probability distribution of luminance at the pixel follows.

In the process executed by the controller 22a, as illustrated in FIG. 21, after step S2, that is, after the probability distribution determination part 203 calculates the two specific parameters μ and σ for each pixel, the filter part 301 performs low-pass filtering on the two specific parameters μ and σ for each pixel. Specifically, for the parameter μ for each pixel (two-dimensional distribution information of the parameter μ) and the parameter σ for each pixel (two-dimensional distribution information of the parameter μ), the filter part 301 performs a process of removing high-frequency components using a low-pass filter. As the low-pass filter, a Butterworth filter, a first-class Chebyshev filter, a second-class Chebyshev filter, a Bessel filter, a finite impulse response (FIR) filter, or the like may be used. The low-pass filtering may be performed only in the direction corresponding to the shape of a pattern (e.g., a line-and-space pattern).

Then, the artificial image generation part 204 generates an artificial image based on the two specific parameters μ and σ for each pixel, which have been subjected to the low-pass filtering (step S12 and step S4).

Specifically, the artificial image generation part 204 sequentially generates artificial frame images for the number of frames specified by the user based on the two specific parameters μ and σ, which have been subjected to the low-pass filtering (step S12). More specifically, the artificial image generation part 204 generates, for each pixel, random numbers for the number of the specified number of frames, based on, for example, the two specific parameters μ and σ for each pixel, which have been subjected to the low-pass filtering in step S11.

Next, the artificial image generation part 204 generates an artificial image by averaging the generated artificial frame images (step S4).

The generated artificial image is used for measurement by the measurement part 205 and analysis by the analysis part 206.

According to the present embodiment, the following effects are achieved.

That is, in the first embodiment and the like, the luminance of a certain pixel in an artificial frame image is determined from the luminance probability distribution of the pixel simply by using random numbers, and thus is not affected by the luminance of pixels located around the pixel. However, when determining the luminance of a certain pixel in an artificial frame image, it is preferable to consider the luminance of the pixels around the pixel. This is because a portion irradiated with a continuously emitted electron beam is affected by electrostatic charge, and thus it is impossible to create a completely independent state. In contrast, in the present embodiment, as described above, by performing the low-pass filtering, it is possible to obtain artificial frame images where the luminance of each pixel looks like luminance generated using random numbers obtained considering the luminance around the pixel, from the luminance probability distribution of the pixel. That is, according to the present embodiment, it is possible to obtain more appropriate artificial frame images, which reflect the shape of an actually imaged pattern (that is, which reflect process noise), and thus it is possible obtain an appropriate artificial image.

In the present embodiment, since the low-pass filtering is performed only in the direction corresponding to the shape of the pattern, the artificial frame images and the artificial image are not blurred by the low-pass filtering.

In the above description, the low-pass filtering is performed for both of the specific parameters μ and σ, but may be performed for only one of the parameters.

In addition, an infinite frame artificial image may be generated based on the specific parameters μ and σ after the low-pass filtering, as in the method according to the fourth embodiment.

### Sixth Embodiment

In the first embodiment and the like, the artificial image generation part 204 generates one artificial image using random numbers based on a luminance probability distribution for each pixel, and the measurement part 205 measures the feature amount of the pattern on the wafer W based on the one artificial image.

In contrast, in the present embodiment, the artificial image generation part 204 generates multiple artificial images using random numbers based on the luminance probability distribution for each pixel. Then, the measurement part 205 measures the feature amount of the pattern on the wafer W based on each of the multiple artificial images, and calculates a statistical amount of the measured feature amount.

Specifically, in the present embodiment, the artificial image generation part 204 repeats the following operations Q times (Q≥2):

(X) generating P artificial frame images (P≥2) by generating random numbers from two specific parameters μ and σ, which determine a log-normal distribution that a probability distribution of luminance for each pixel follows; and
(Y) generating an artificial image by averaging the generated P artificial frame images.

As a result, Q artificial images are generated.

Then, the measurement part 205 calculates, as the feature amount of the pattern on the wafer W, edge coordinates of the pattern based on, for example, each of the Q artificial images, and calculates and acquires, from the calculated Q edge coordinates, an average value of the edge coordinates as a statistic value of the edge coordinates.

Unlike the present embodiment, random numbers may affect the feature amount in the case where one artificial image is generated by averaging a large number of artificial frame images generated using the random numbers and the feature amount is calculated from the one artificial image. In addition, the feature amount is inaccurate when generating one artificial image by averaging artificial frame images, which are not large in number, generated using random numbers and calculating the feature amount from the one artificial image.

In contrast, in the present embodiment, multiple artificial images obtained by averaging artificial frame images, which are not large in number, using random numbers are generated, a feature amount is calculated based on each of the multiple artificial images, and a statistical value of the feature amount is obtained. Therefore, according to the present embodiment, the influence of random numbers is small, and it is possible to obtain a more accurate feature amount. When it is possible to accurately obtain the edge coordinates as the feature amount, it is possible to calculate an accurate LER or LWR of the pattern. In addition, the LER or LWR of the pattern may be calculated directly as a feature amount without calculating the average value of the edge coordinates.

### Seventh Embodiment

In the sixth embodiment, as described above, multiple (Q) artificial images are generated, the feature amount of the pattern on the wafer W is calculated for each of multiple artificial images, and an average value is calculated for the feature amounts.

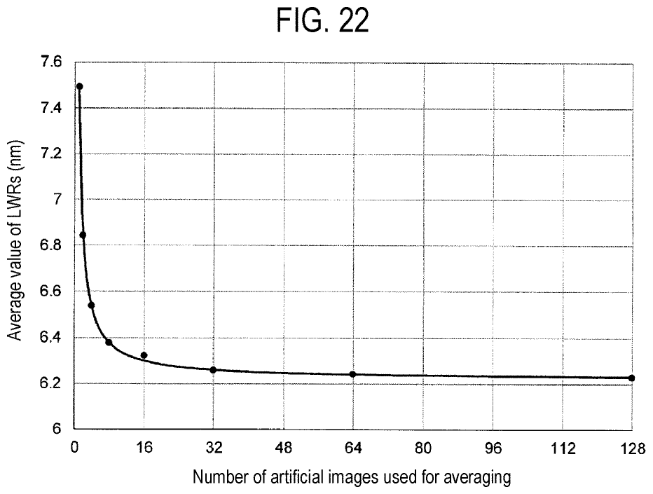

FIG. 22 is a diagram showing a relationship between an average value of LWRs of a pattern as the feature amount of the pattern on a wafer W and the number of artificial images used for calculating the average value in the sixth embodiment.

As shown in the figure, the average value of LWRs of the pattern decreases as the number of artificial images used to calculate the average value increases, and converges to a certain value; that is, the noise decreases. Therefore, in order to obtain an average value of LWRs of the pattern with less noise, the number of artificial images used for calculating the average value and the number of times the feature amount of the artificial image is calculated may be increased. However, when the number of artificial images used for calculating the average value and the number of times the feature amount is calculated are increased, the calculation takes time and throughput decreases.

According to an examination performed by the inventor in this regard, the relationship between the average value of LWRs of the pattern in the figure and the number of artificial images used for calculating the average value may be approximated by a regression formula represented by the following Equation 2.

y=a/x+b (2)

y: an average value of LWRs of a pattern on a wafer W;
x: a number of artificial images used for calculating the average value; and
a, b: positive constants.

In addition, the determination coefficient R² of the regression formula is 0.999.

Therefore, in the present embodiment, the artificial image generation part 204 generates multiple artificial images as in the sixth embodiment. Here, it is assumed that 16 artificial images are generated.

Then, the measurement part 205 calculates average values of LWRs of the pattern in T artificial images included in the multiple artificial images multiple times while changing the value of T. Specifically, when 16 artificial images are generated, for example, 16 average values (the average value of LWRs of the pattern in the first artificial image, the average value in the first and second artificial images, the average value in the first to third artificial images, . . . , the average value in the first to sixteenth artificial images) are calculated.

In addition, the measurement part 205 fits Equation 2 to the above calculation results (in the above example, to 16 average values of LWRs of the pattern), and acquires an intercept b of fitted Equation 2 as a statistical amount of LWRs of the pattern.

The acquired statistical amount of LWRs of the pattern has less noise even though the number of the artificial images generated by the artificial image generation part 204 is small. In other words, in the present embodiment, a statistical amount of LWRs of the pattern having less noise can be easily obtained.

The equation used for the fitting is not limited to Equation 2, and may be an equation of a specific monotonically decreasing function represented by, for example, Equations 3 and 4 as follows. The specific monotonically decreasing function is a function in which the number T of the artificial images used for calculating the average value of LWRs of the pattern is used as an independent variable, the average value is used as a dependent variable, and both the dependent variable and the decrease rate of the dependent variable monotonically decrease.

y=a/x^{c}+b (3)

y=ke^{-ax}+b (4)

y: an average value of LWRs of a pattern on a wafer W;
x: the number of artificial images used for calculating the average value; and
a, b, c, k: positive constants.

### Eighth Embodiment

In the present embodiment, the artificial image generation part 204 generates multiple artificial images, as in the sixth embodiment and the seventh embodiment. Here, it is assumed that 16 artificial images are generated.

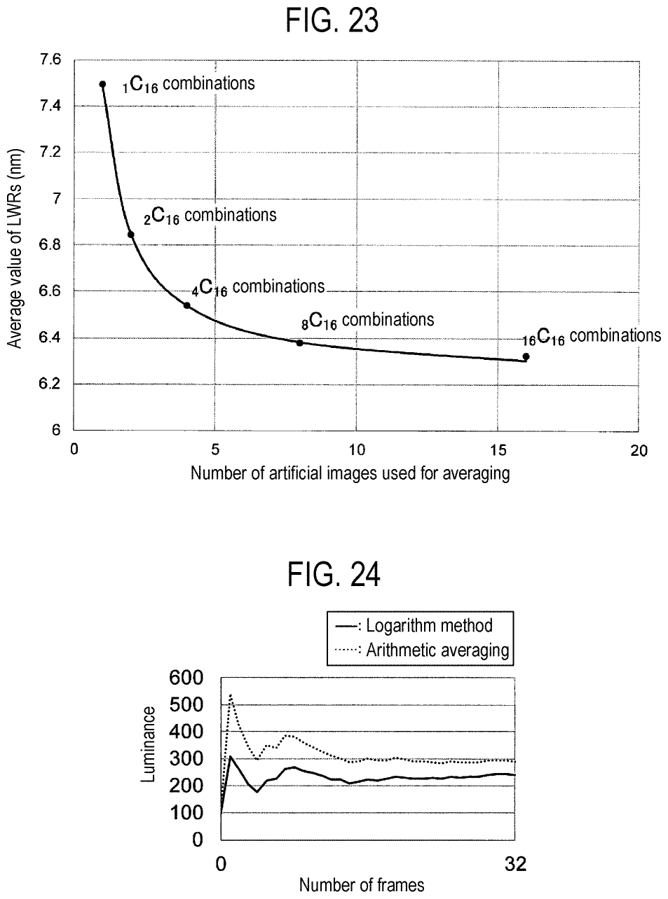

In the present embodiment, the measurement part 205 forms different combinations of U artificial images selected from among the multiple artificial images, and performs calculation of the average value of LWRs of the pattern for each combination multiple times while changing the number of selections U. Specifically, when 16 artificial images are generated, the measurement part 205 forms ₁₆C₁ combinations of one artificial image selected from among the 16 artificial images as shown in FIG. 23, and calculates, for each combination, an average value of LWRs of the pattern. Similarly, the measurement part 205 forms ₁₆C₂ combinations of two artificial images selected from among the 16 artificial images and calculates an average value of LWRs of the pattern for each combination, forms ₁₆C₃ combinations of three artificial images selected from among the 16 artificial images and calculates an average value of LWRs of the pattern for each combination, . . . , and forms ₁₆C₁₆ combinations of 16 artificial images selected from among the 16 artificial images and calculates an average value of LWRs of the pattern (for each combination).

In addition, the measurement part 205 fits Equation 2 to the above calculation result (in the above example, to the (₁₆C₁+₁₆C₂+₁₆C₃+ . . . +₁₆C₁₆) average values of LWRs of the pattern), and acquires an intercept b of the fitted Equation 2 as a statistical amount of LWRs of the pattern. The acquired statistical amount of LWRs of the pattern has little noise even though the number of artificial images generated by the artificial image generation part 204 is small. In addition, in the present embodiment, the number of average values (the number of plots) of LWRs of the pattern used for fitting is much larger than that in the seventh embodiment. Therefore, it is possible to perform fitting more accurately so that a more accurate statistical amount of LWRs of the pattern can be obtained.

The equation used for the fitting is not limited to Equation 2, as in the seventh embodiment, but may be an equation of a specific monotonically decreasing function represented by, for example, Equation 3 or Equation 4.

The sixth to eighth embodiments are also applicable to the case where the specific parameters μ and σ after the low-pass filtering are used for generating an artificial image, as in the fifth embodiment.

In the above examples, since the histogram in FIG. 2 follows a log-normal distribution, the probability distribution determination part 203 determines, for each pixel, a luminance probability distribution according to the log-normal distribution.

According to further examinations performed by the inventor, the histogram in FIG. 2 follows the sum of multiple log-normal distributions, a Weibull distribution, or a gamma-Poisson distribution. In addition, the histogram also follows a combination of a single log-normal distribution or multiple log-normal distributions and a Weibull distribution, a combination of a single log-normal distribution or multiple log-normal distributions and a gamma-Poisson distribution, or a combination of a Weibull distribution and a gamma-Poisson distribution. The histogram also follows a combination of a single log-normal distribution or multiple log-normal distributions, a Weibull distribution, and a gamma-Poisson distribution. Accordingly, the luminance probability distribution determined by the probability distribution determination part 203 for each pixel may follow at least one of a log-normal distribution or a sum of log-normal distributions, a Weibull distribution, and a gamma-Poisson distribution, or a combination thereof.

In the above description, an imaging target is assumed to be a wafer, but the imaging target is not limited thereto. The imaging target may be, for example, another type of substrate, or may be other than a substrate.

In the above description, a particular averaging method used for averaging the luminance of pixels and LWRs of a pattern is not described, but the averaging method is not limited to simple averaging, that is, arithmetic averaging. The averaging method may be, for example, a method in which an averaging target (e.g., the luminance Cᵢ of pixels of coordinates (x, y)) is converted into a logarithm and the average value of the logarithm is converted into an antilogarithm (e.g., the luminance C_{x,y} of the pixels of the coordinates (x, y)) (hereinafter, referred to as a logarithmic method), as represented by Equation 5.

$$\begin{matrix}[ Number 2 ] & \\ {C}_{x , y} = exp ( \frac{1}{n} {\sum }_{i = 1}^{n} ln ( {C}_{i} ) ) & ( 5 )\end{matrix}$$

In the case of the logarithmic method described above, for example, as shown in FIG. 24, it is possible to obtain information on the luminance of pixels with less noise, even with a small number of artificial frames.

In addition, the averaging method may be, for example, a method in which an averaging target is converted into a logarithm, a root mean square of the logarithm is calculated, and the root mean square is converted into an antilogarithm, as represented by Equation 6.

$$\begin{matrix}[ Number 3 ] & \\ {C}_{x , y} = exp ( \frac{1}{n} \sqrt{{\sum }_{i = 1}^{n} {ln ( {C}_{i} )}^{2}} & ( 6 )\end{matrix}$$

In the above description, the control device for the scanning electron microscope is used as an image processing device in each embodiment. Alternatively, a host computer configured to perform analysis or the like based on an image of a processing result in a semiconductor manufacturing apparatus, such as a coating development processing system, may be used as the image processing device according to each embodiment.

In the above description, a charged particle beam is an electron beam, but is not limited thereto. The charged particle beam may be, for example, an ion beam.

In the above description, image processing of a line-and-space pattern has been described as an example in each embodiment. However, each embodiment is also applicable to images of other patterns, such as contact hole patterns and pillar patterns.

It should be understood that the embodiments disclosed herein are illustrative and are not limiting in all aspects. The above embodiments may be omitted, replaced, or modified in various forms without departing from the scope and spirit of the appended claims.

The following configurations also fall within the technical scope of the present disclosure.

(1) An image processing method of processing an image, the image processing method including:

(A) a step of acquiring multiple frame images, each of which is obtained by scanning an imaging target one time with a charged particle beam;
(B) a step of determining, from the multiple frame images, a luminance probability distribution for each pixel; and
(C) a step of generating an image of the imaging target, which corresponds to an image obtained by averaging multiple different frame images generated based on the luminance probability distribution for each pixel.

In the item (1), multiple frame images of an imaging target are acquired, and a luminance probability distribution following a log-normal distribution or the like is determined for each pixel from the acquired multiple frame images. Then, an image of the imaging target (an artificial image) is generated by averaging the multiple different frame images (artificial frame images) generated based on the luminance probability distribution for each pixel. According to this method, it is possible to generate, from frame images, an artificial image obtained by averaging a large number of artificial frame images, and thus it is possible to reduce image noise in the artificial image.

(2) The image processing method of item (1), wherein the luminance probability distribution follows at least one of a log-normal distribution or a sum of log-normal distributions, a Weibull distribution, and a gamma-Poisson distribution, or a combination thereof.

(3) The image processing method of item (1) or (2), wherein the imaging target is a substrate on which a pattern is formed, and wherein the image processing method further includes a step of measuring a feature amount of the pattern based on an image of the substrate as the image of the imaging target generated in the step (C).

(4) The image processing method of item (3), wherein the feature amount of the pattern is at least one of a line width of the pattern, a line width roughness of the pattern, and a line edge roughness of the pattern.

(5) The image processing method of any one of items (1) to (4), wherein the imaging target is a substrate on which a pattern is formed, and the image processing method further includes a step of performing analysis of the pattern based on the image of the substrate as the image of the imaging target generated in the step (C).

(6) The image processing method of item (5), wherein the analysis is at least one of frequency analysis of the line width roughness of the pattern and frequency analysis of the line edge roughness of the pattern.

(7) The image processing device of any one of items (1) to (6), wherein the step (C) includes:

a step of correcting, for each pixel in each of the frame images of second and subsequent frames, luminance of the pixel based on a temporal change in the luminance of the pixel in a series of the frame images; and
a step of determining a luminance probability distribution for each pixel from the multiple frame images including the frame images of the second and subsequent frames after the correction.

(8) The image processing method of any one of items (1) to (7), wherein the step (C) includes:

a step of correcting each of the frame images of second and subsequent frames based on a shift amount in an image plane from a frame image of a first frame; and
a step of determining a luminance probability distribution for each pixel from the multiple frame images including the frame images of the second and subsequent frames after the correction.

(9) The image processing method of any one of items (1) to (8), wherein the luminance probability distribution follows a log-normal distribution,

the step (B) is a step of calculating two parameters μ and σ, which determine the log-normal distribution for each pixel, and
in the step (C), the image of the imaging target is generated based on the two parameters μ and σ.

(10) The image processing device of item (9), further including a step of performing low-pass filtering on at least one of the two parameters μ and σ for each pixel calculated through the step of calculating,

wherein, in the step (C), the image of the imaging target is generated based on the two parameters μ and σ for each pixel, at least one of which has been subjected to the low-pass filtering.

(11) The image processing method of item (10), wherein the imaging target is a substrate on which a pattern is formed, and

in the step of performing low-pass filtering, the low-pass filtering is performed on at least one of the two parameters μ and σ for each pixel only in a direction corresponding to a shape of the pattern.

(12) The image processing method of any one of items (1) to (11), wherein, in the step (C), based on the luminance probability distribution for each pixel, the multiple different frame images are sequentially generated, and

the image of the imaging target is generated by averaging the generated multiple different frame images.

(13) The image processing method of items (1) to (12), wherein the different frame images are images obtained by setting a luminance of each pixel to a random value generated based on the luminance probability distribution for each pixel.

(14) The image processing method of any one of items (1) to (11), wherein in the step (C), an image obtained by setting the luminance of each pixel to expected values of the luminance probability distribution is generated as the image of the imaging target.

(15) The image processing method of item (12), wherein the imaging target is a substrate on which a pattern is formed, and the step (C) further comprises acquiring a statistical amount of a feature amount based on measurement result by generating multiple images of the substrate as multiple images of the imaging target, and by performing measurement of the feature amount of the pattern based on each of the multiple images of the substrate.

(16) The image processing method of item (15), wherein the feature amount of the pattern in the step of acquiring the statistical amount is edge coordinates of the pattern, and the statistical amount of the feature amount of the pattern is an average value of the edge coordinates.

(17) The image processing method of item (15), wherein the feature amount of the pattern in the step of acquiring the statistical amount is a line width roughness of the pattern, and the step of acquiring the statistical amount includes:

a step of calculating, multiple times, an average value of line width roughnesses in T images of the substrate included in the multiple images of the substrate generated in the step C while changing a value of T; and
a step of fitting, to a calculation result, a monotonically decreasing function in which the number of artificial images T used for calculating the average value of line width roughnesses of the pattern is used as an independent variable, and both a dependent variable and a decrease rate of the dependent variable monotonously decrease, and acquiring an intercept of the monotonous decrease function as the statistical amount of the line width roughness of the pattern.

(18) The image processing method of item (15), wherein the feature amount of the pattern in the step of acquiring the statistical amount is a line width roughness of the pattern, and the step of acquiring the statistical amount includes:

a step of forming multiple combinations of U images selected from the multiple images of the substrate generated in the step (C) and calculating, multiple times, the average value of line width roughnesses of the pattern for each combination while changing a value of a number of selections U; and
a step of fitting, to a calculation result, a monotonically decreasing function in which the number of selections U is used as an independent variable, and both a dependent variable and a decrease rate of the dependent variable monotonically decrease, and acquiring an intercept of the monotonically decreasing function as the statistical amount of the line width roughness of the pattern.

(19) The image processing method of any one of items (1) to (18), wherein, during the averaging,

an averaging target is converted into a logarithm, and an average value of the logarithm is converted into an antilogarithm, or
the averaging target is converted into a logarithm, a root mean square of the logarithm is calculated, and the root mean square of the logarithm is converted into an antilogarithm.

(20) An image processing device for processing an image, the image processing device including:

an acquisition part configured to acquire multiple frame images, each of which is obtained by scanning an imaging target one time with a charged particle beam;
a probability distribution determination part configured to determine, from the multiple frame images, a luminance probability distribution for each pixel; and
an image generation part configured to generate an image of the imaging target, which corresponds to an image obtained by averaging multiple different frame images generated based on the luminance probability distribution for each pixel.

### EXPLANATION OF REFERENCE NUMERALS

20: control device, 201: frame image generation part, 202: acquisition part, 203: probability distribution determination part, 204: frame image generation part, W: wafer

1. An image processing method of processing an image, the image processing method comprising:
(A) a step of acquiring multiple frame images, each of which is obtained by scanning an imaging target with a charged particle beam;
(B) a step of determining, from the multiple frame images, a luminance probability distribution for each pixel; and
(C) a step of generating an image of the imaging target, which corresponds to an image obtained by averaging multiple different frame images generated based on the luminance probability distribution for each pixel.

2. The image processing method of claim 1, wherein the luminance probability distribution follows at least one of a log-normal distribution or a sum of log-normal distributions, a Weibull distribution, and a gamma-Poisson distribution, or a combination thereof.

3. The image processing method of claim 1, wherein the imaging target is a substrate on which a pattern is formed, and
the image processing method further comprises a step of measuring a feature amount of the pattern based on an image of the substrate as the image of the imaging target generated in the step (C).

4. The image processing method of claim 3, wherein the feature amount of the pattern is at least one of a line width of the pattern, a line width roughness of the pattern, and a line edge roughness of the pattern.

5. The image processing method of claim 1, wherein the imaging target is a substrate on which a pattern is formed, and
the image processing method further comprises a step of performing analysis of the pattern based on the image of the substrate as the image of the imaging target generated in the step (C).

6. The image processing method of claim 5, wherein the analysis is at least one of frequency analysis of the line width roughness of the pattern and frequency analysis of the line edge roughness of the pattern.

7. The image processing method of claim 1, wherein the step (C) includes:
a step of correcting, for each pixel in each of the frame images of second and subsequent frames, luminance of the pixel based on a temporal change in the luminance of the pixel in a series of the frame images; and
a step of determining a luminance probability distribution for each pixel from the multiple frame images including the frame images of the second and subsequent frames after the correction.

8. The image processing method of claim 1, wherein the step (C) includes:
a step of correcting each of the frame images of second and subsequent frames based on a shift amount in an image plane from a frame image of a first frame; and
a step of determining a luminance probability distribution for each pixel from the multiple frame images including the frame images of the second and subsequent frames after the correction.

9. The image processing method of claim 1, wherein the luminance probability distribution follows a log-normal distribution,
the step (B) is a step of calculating two parameters μ and σ, which determine the log-normal distribution for each pixel, and
in the step (C), the image of the imaging target is generated based on the two parameters μ and σ.

10. The image processing method of claim 9, further comprising:
a step of performing low-pass filtering on at least one of the two parameters μ and σ for each pixel calculated through the step of calculating,
wherein, in the step (C), the image of the imaging target is generated based on the two parameters p and a for each pixel, at least one of which has been subjected to the low-pass filtering.

11. The image processing method of claim 10, wherein the imaging target is a substrate on which a pattern is formed, and
in the step of performing low-pass filtering, the low-pass filtering is performed on at least one of the two parameters p and a for each pixel only in a direction corresponding to a shape of the pattern.

12. The image processing method of claim 1, wherein, in the step (C), based on the luminance probability distribution for each pixel, the multiple different frame images are sequentially generated, and
the image of the imaging target is generated by averaging the generated multiple different frame images.

13. The image processing method of claim 1, wherein the different frame images are images obtained by setting a luminance of each pixel to a random value generated based on the luminance probability distribution for each pixel.

14. The image processing method of claim 1, wherein, in the step (C), an image obtained by setting the luminance of each pixel to expected values of the luminance probability distribution is generated as the image of the imaging target.

15. The image processing method of claim 12, wherein the imaging target is a substrate on which a pattern is formed, and
the step (C) further comprises acquiring a statistical amount of a feature amount based on measurement result by generating multiple images of the substrate as multiple images of the imaging target, and by performing measurement of the feature amount of the pattern based on each of the multiple images of the substrate.

16. The image processing method of claim 15, wherein the feature amount of the pattern in the step of acquiring the statistical amount is edge coordinates of the pattern, and
the statistical amount of the feature amount of the pattern is an average value of the edge coordinates.

17. The image processing method of claim 15, wherein the feature amount of the pattern in the step of acquiring the statistical amount is a line width roughness of the pattern, and
the step of acquiring the statistical amount includes:
a step of calculating, multiple times, an average value of line width roughnesses in T images of the substrate included in the multiple images of the substrate generated in the step C while changing a value of T; and
a step of fitting, to a calculation result, a monotonically decreasing function in which the number of artificial images T used for calculating the average value of line width roughnesses of the pattern is used as an independent variable, and both a dependent variable and a decrease rate of the dependent variable monotonously decrease, and acquiring an intercept of the monotonous decrease function as the statistical amount of the line width roughness of the pattern.

18. The image processing method of claim 15, wherein the feature amount of the pattern in the step of acquiring the statistical amount is a line width roughness of the pattern, and
the step of acquiring the statistical amount includes:
a step of forming multiple combinations of U images selected from the multiple images of the substrate generated in the step (C) and calculating, multiple times, the average value of line width roughnesses of the pattern for each combination while changing a value of a number of selections U; and
a step of fitting, to a calculation result, a monotonically decreasing function in which the number of selections U is used as an independent variable, and both a dependent variable and a decrease rate of the dependent variable monotonically decrease, and acquiring an intercept of the monotonically decreasing function as the statistical amount of the line width roughness of the pattern.

19. The image processing method of claim 1, wherein, during the averaging,
an averaging target is converted into a logarithm, and an average value of the logarithm is converted into an antilogarithm, or
the averaging target is converted into a logarithm, a root mean square of the logarithm is calculated, and the root mean square of the logarithm is converted into an antilogarithm.

20. An image processing device for processing an image, the image processing device comprising:
an acquisition part configured to acquire multiple frame images, each of which is obtained by scanning an imaging target with a charged particle beam;
a probability distribution determination part configured to determine, from the multiple frame images, a luminance probability distribution for each pixel; and
an image generation part configured to generate an image of the imaging target, which corresponds to an image obtained by averaging multiple different frame images generated based on the luminance probability distribution for each pixel.
